(19) United States
(12) Patent Application Publication
(10) Pub. No.: US 2004/0063224 A1
(43) Pub. Date: Apr. 1, 2004

(54) Feedback control of a chemical mechanical polishing process for multi-layered films

(75) Inventor: J. Young J. Paik, Campbell, CA (US)

Correspondence Address: Patent Counsel, MS/2061, Legal Affairs Department, Applied Materials, Inc., P.O. Box 450A, Santa Clara, CA, 95052, US

(73) Assignee: Applied Materials, Inc., Santa Clara, CA

(21) Appl. No.: 10/665,165

(22) Filed: Sep. 18, 2003

Related U.S. Application Data
(60) Provisional application No. 60/411,735, filed on Sep. 18, 2002.

(51) Int. Cl. H01L 21/00; H01L 21/302; H01L 21/461

(52) U.S. Cl. 438/5; 438/692; 216/89

(57) ABSTRACT

A computer-implemented method for updating a process recipe in a CMP process for a multi-layer wafer wherein the CMP process has at least one control parameter capable of being controlled includes the steps of (a) inputting a model comprising at least one control parameter for CMP processing of a wafer having at least first and second layers, said model comprising a first component that predicts a value for a characteristic of the first layer and a second component that predicts a value for a characteristic of the second layer; (b) determining a process recipe based upon the model of step (a); (c) receiving a measured value of the characteristic of the first layer and/or the characteristic of the second layer for a wafer processed according to the process recipe of step (b); and (d) determining an updated model based upon the difference between the measured value and the predicted value of the characteristic.

### RELATED APPLICATIONS

This application claims priority under 35 U.S.C. § 119(e) to copending application U.S. Ser. No. 60/411,735, filed on Sep. 18, 2002, which is incorporated herein by reference.

### FIELD OF THE INVENTION

The present invention generally relates to the planarization of substrates, in particular, semiconductor wafers, and more particularly to a method and apparatus for providing feedback and feed forward control of the planarization process for multi-layer films.

### BACKGROUND OF THE INVENTION

Chemical-mechanical polishing (CMP) is used in semiconductor fabrication processes for obtaining full planarization of semiconductor wafers. The method involves removing material, e.g., a sacrificial layer of surface material, from the wafer (typically, silicon dioxide (SiO₂)) using mechanical contact and chemical erosion. Polishing flattens out height differences, since areas of high topography (hills) are removed faster than areas of low topography (valleys).

CMP typically utilizes an abrasive slurry dispersed in an alkaline or acidic solution to planarize the surface of the wafer through a combination of mechanical and chemical actions. Generally, a CMP tool includes a polishing device (having an attached wafer to be polished) positioned above a rotatable circular platen on which a polishing pad is mounted. In use, the platen may be rotated and an abrasive slurry is introduced onto the polishing pad. Once the slurry has been applied to the polishing pad, a downward force is applied to a rotating head to press the attached wafer against the pad. As the wafer is pressed against the polishing pad, the wafer is mechanically and chemically polished. The effectiveness of a CMP process may be measured by its polishing rate, and by the resulting finish (absence of small-scale roughness) and flatness (absence of large-scale topography) of the substrate surface.

As semiconductor processes are scaled down, the importance of CMP to the fabrication process increases. In particular, it is increasingly important to understand and control the factors leading to variation in polishing rate and wafer thickness, i.e., wafer non-uniformity. A variety of factors may contribute to variation across the surface of a wafer during polishing. Process control, including feedback control to correct for any drift or deviation in the process, is used in the semiconductor industry to maintain wafer properties within a target range.

In CMP process control, an initial model is developed to describe the relationship of the wafer properties and the processing parameters of interest (the latter being manipulated by a processing recipe). The model is used to control the run-to-run uniformity of the polishing process and to provide a feedback loop for updating the processing recipe. Briefly, one or more wafers are processed according to a first polishing recipe. A thickness measurement of the polished wafer is taken to obtain a wafer thickness profile, which is compared to the predicted wafer thickness calculated by the model. If the measured wafer thickness indicates deviation from the desired results, those deviations are used in an optimization process to update the polishing model. The updated model is then used to progressively optimize the polishing recipe so as to improve or maintain wafer thickness within a target value.

Current semiconductor fabrication involves multiple processing steps, many of which require the deposition, masking and removal of film layers from the wafer substrate. Semiconductor fabrication often requires that multiple layers be polished in a single step. For example, a main layer and a buffer or protecting layer typically are polished at the same time. Current industrial practice treats the multi-layer films as a monolith film in designing and controlling the polishing operation. In reality, the different layers have different polishing profiles and treatment of the multi-layer film as a monolayer film leads to errors in the polishing process. Multiple layers having different polishing characteristics manifest different polishing behavior, which are difficult to describe in current single-layer models.

Models and methods for process control in the CMP processing of multi-layer films are needed.

### SUMMARY OF THE INVENTION

The present invention provides a model and method for process control in the CMP processing of multi-layer films. The present invention decouples the non-linear polishing behavior of multi-layer films and provides a linear expression for polishing behavior that is used to mathematically model CMP polishing of multi-layer films. The model of the present invention defines the polishing process as a series of polishing steps, such that one or more polishing steps are associated with removal of a first film layer and one or more different polishing steps are associated with removal of a second film layer. The model treats polishing of each layer independently and develops a model for each layer. The models (or sub-models) are then combined in a linear relationship to define a model for the entire film. The model is used to predict and optimize the polishing recipe of a multi-layer film so as to improve and/or maintain wafer thickness or other wafer characteristic within a target value.

In one aspect of the present invention, a computer-implemented method for updating a process recipe in a CMP process for a multi-layer wafer includes the steps of (a) inputting a model for CMP processing of a wafer having at least first and second layers comprising at least one control parameter, the model comprising a first component that predicts a value for a characteristic of the first layer and a second component that predicts a value for a characteristic of the second layer; (b) determining a process recipe based upon the model of step (a); (c) receiving a measured value of the characteristic of the first layer and/or the characteristic of the second layer for a wafer processed according to the process recipe of step (b); and (d) determining an updated model based upon the difference between the measured value and the predicted value of the characteristic.

In another aspect of the present invention, a method of controlling a characteristic of a wafer in a CMP operation includes the steps of (a) providing a model for CMP processing of a wafer having at least first and second layers comprising at least one control parameter capable of being controlled, the model comprising a first component that predicts a value for a characteristic of the first layer and a second component that predicts a value for a characteristic of the second layer; (b) polishing a wafer using a first polishing recipe based upon the model of step (a); (c) measuring the wafer characteristic for a wafer processed according to the process recipe of step (b); and (d) determining an updated model based upon the difference between the measured value and the predicted value of the wafer characteristic.

In one or more embodiments of the present invention, the model defines a first polishing recipe for the first layer of the wafer and a second polishing recipe for the second layer of the wafer.

In one or more embodiments of the present invention, the model is defined as:

Yₜ=Y_{A}+Y_{B},

where

Yₜ is the model for a CMP process for a multi-layer wafer

Y_{A} is the model for a CMP process for the first layer of the wafer

Y_{B} is the model for a CMP process for the second layer of the wafer

In one or more embodiments of the present invention, the characteristic of the wafer is film thickness, and/or the control parameter is polishing time.

In one or more embodiments of the present invention, the model defines a plurality of regions on a wafer and identifies a wafer material removal rate in a polishing step of a polishing process for each of the regions, wherein the polishing process comprises a plurality of polishing steps. The plurality of regions in the model of step (a) includes regions extending radially outward from a center point on the wafer.

In one or more embodiments of the present invention, the polishing of step (b) comprises polishing the wafer at a plurality of polishing stations. The polishing step can be carried out at three polishing stations.

In one or more embodiments of the present invention, calculating the updated polishing model of step (d) comprises calculating updated model for each of the plurality of polishing stations. The updated polishing model for each of the plurality of polishing stations accounts for the tool state of the individual polishing stations.

In one or more embodiments of the present invention, the polishing of step (b) is carried out at a plurality of polishing stations, and the wafer characteristic for each of the subsequent polishing stations is provided by the prediction from previous stations.

In another aspect of the present invention, development of a model includes (e) measuring pre-polished wafer thickness on one or more wafers; (f) polishing the one or more wafers, wherein polishing comprises polishing the one or more wafers in a plurality of polishing steps; (g) measuring the wafer material removal rate for the one or more wafers after each of the polishing steps of step (g); (h) providing a model defining the effect of tool state on polishing effectiveness; and (i) recording the pre-polished and post-polished wafer thicknesses on a recordable medium.

In one or more embodiments of the present invention, model development further includes fitting the data to a linear or non-linear curve that establishes a relationship between the material removal rate of the wafer and a polishing parameter of interest.

### BRIEF DESCRIPTION OF THE DRAWINGS

Various objects, features, and advantages of the present invention can be more fully appreciated with reference to the following detailed description of the present invention when considered in connection with the following drawing, in which like reference numerals identify like elements. The following drawings are for the purpose of illustration only and are not intended to be limiting of the present invention, the scope of which is set forth in the claims that follow.

FIG. 1 is a perspective view of a chemical mechanical polishing apparatus.

FIG. 2 is a cross-sectional view of a multi-layer film to be polished according to one or more embodiments of the present invention.

FIG. 3 is a flow diagram generally illustrating model development.

FIG. 4 is a plot of oxide material removal (A) across the surface of a substrate for successive polishing steps in a polishing recipe.

FIG. 5 is a schematic illustration of a wafer showing regions defined for a thickness profile model.

FIG. 6 is a schematic illustration of model development for a CMP process using two platens with different polishing recipes, as contemplated by at least some embodiments of the present invention.

FIG. 7 is a flow diagram of the feedback loop used in a CMP polishing operation, as contemplated by at least some embodiments of the present invention.

FIG. 8 is a block diagram of a computer system for use in at least some embodiments of the present invention.

### DETAILED DESCRIPTION OF THE INVENTION

In some CMP applications, such as copper interconnects, the CMP system polishes several different materials of widely varying physical and chemical properties. For example, an initial polishing step might remove the thick top material at a high polishing rate for maximum throughput. Then the material is removed at a slower rate down to a point near the final layer to be polished. This slower polishing rate has higher precision and enables accurate detection of a thin barrier layer. A very high-precision polishing chemistry with a low removal rate may be used to ensure that the process stops at exactly the right point, with all of the covering layer removed, but without damaging or over-polishing the intended final layer. At this point the planarized wafer is ready for post-polish cleaning and the subsequent process steps.

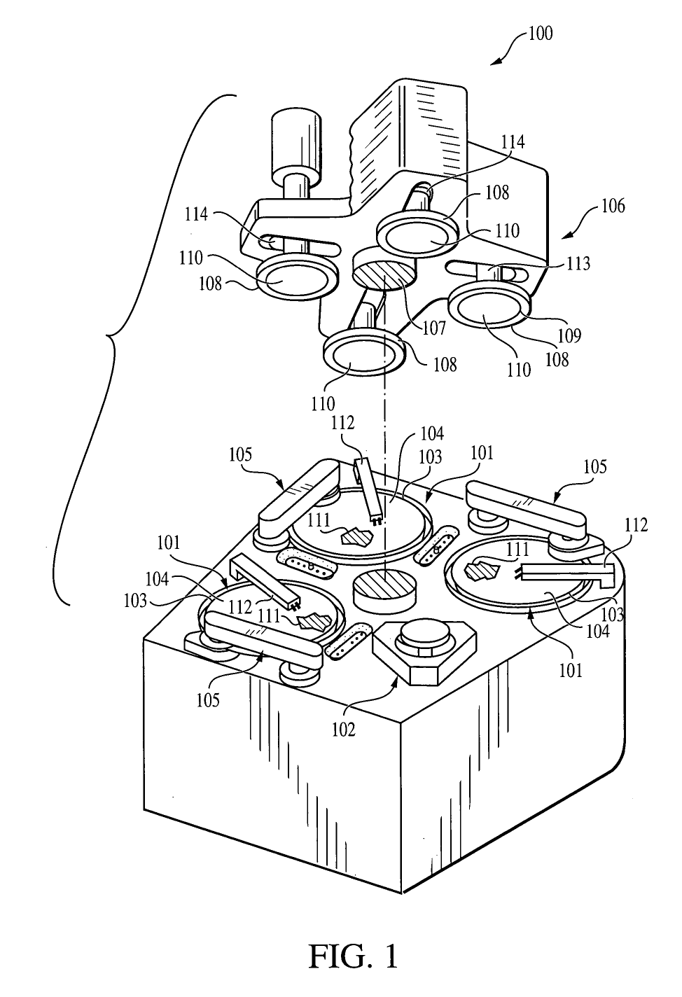

FIG. 1 shows a perspective view of a typical CMP apparatus 100 for polishing one or more substrates 110. The CMP apparatus 100 includes a series of polishing stations 101 and a transfer station 102 for loading and unloading substrates. Each polishing station includes a rotatable platen 103 on which is placed a polishing pad 104. A source of polishing fluid 112 may be provided to supply polishing fluid 111 to the polishing pad 104. Each polishing station may include an associated pad conditioning apparatus 105 to maintain the abrasive condition of the polishing pad. A rotatable multi-head carousel 106 is supported by center post 107 about which the carousel rotates. The carousel 106 includes multiple carrier heads 108, each of which is capable of independently rotating about its own axis. The carrier head 108 receives a substrate from and delivers a substrate to the transfer station 102. The carrier head provides a controllable load, i.e., pressure on the substrate to push it against the polishing pad when the polishing station and the carrier head are engaged. Some carrier heads include a retaining ring 109 to hold the substrate and help to provide the polishing load. To effectuate polishing, the platen 103 may be rotated (typically at a constant speed). Moreover, individually variable down forces may be applied by each of the carrier heads 108, for example by adjusting retaining ring pressures. The carrier heads 108 holding substrates 110 can rotate on axis 113 and oscillate back and forth in slot 114.

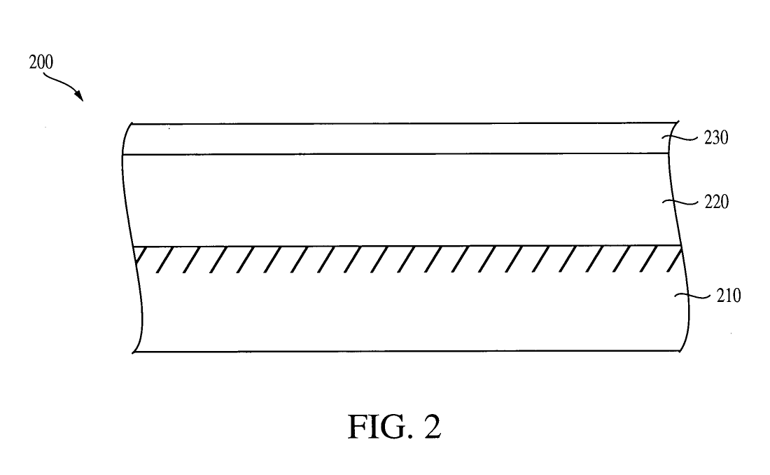

The CMP apparatus described above is exemplary of those that may be used to polish multi-layer films. The polishing process is modeled to provide a format for optimizing the planarization process in a multi-layer film. An exemplary multi-layer product 200 is shown in FIG. 2. The multilayer product 200 includes substrate or wafer 210 on which layers 220 and 230 are deposited. The substrate 210 may be a monolith structure, or it may itself be a substrate having one or more layers or thin films deposited thereon. The main layer 220 is typically deposited on the wafer and is relatively thick, e.g., ˜5000-10,000 Å. An additional layer 230, typically much thinner, e.g., ˜500 Å, is deposited on the main layer 220. Although the main layer is many times greater in thickness than the capping layer, it is not uncommon for the capping layer to be made of a much harder material. For example, the main layer can be a doped silica glass such as boron-phosphorus silica (BPSG) and the capping layer can be tetraethylorthosilicate (TEOS). The capping layer is removed much more slowly than the main layer and requires a disproportionate amount of the polishing resources. Thus the polishing profile for the multi-layer film is non-linear. Non-linear behavior is complex and difficult to model.

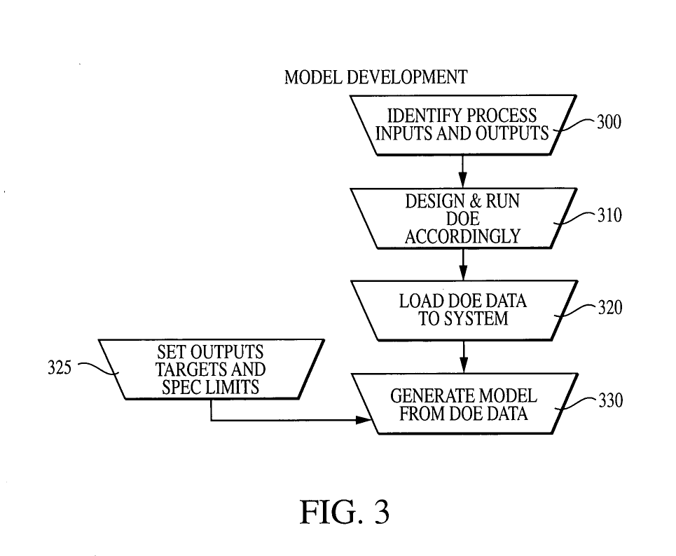

According to at least some embodiments of the present invention, an initial model is developed based upon knowledge of the wafer polishing process, as is shown in a flow diagram (FIG. 3). An initial understanding of the system is acquired in step 300, which is used to design and run a design of experiments (DOE) in step 310. The DOE desirably is designed to establish the relationship between or among variables that have a strong and predictable impact on the processing output one wishes to control, e.g., wafer thickness or wafer uniformity. The DOE provides data relating to process parameters and process outcome, which is then loaded to the advanced process control system in step 320. The advanced processing control system may be a controller or computer that uses the data to create and/or update the model. Processing requirements such as output targets and process specification to be used during operation of the polishing process are determined by the user in step 325, which are combined with the DOE data to generate a working model in step 330.

The model of the present invention defines the polishing process as a series of polishing steps, such that one or more polishing steps are associated with removal of a first film layer and one or more different polishing steps are associated with removal of a second film layer. The model treats polishing of each layer independently and develops a model for each layer. The models (or sub-models) are then combined in a linear relationship to define a model for the entire film. For the purposes of simplicity, the model is developed for a two-layer film; however, it will be immediately apparent to those of ordinary skill in the art that the methodology and apparatus of the present invention can be readily applied to films having more than two layers.

To obtain DOE data, a polishing step is run and, based upon incoming measurements, e.g., pre-polishing and post-polishing wafer thickness measurements, and processing parameter values, a removal rate profile or, equivalently, a wafer thickness profile, can be determined for each layer. Conventionally, data may be acquired empirically, by carrying out a series of experiments over a range of parameter values and over the lifetime of the polishing pad and conditioning disk. Such an approach makes no assumptions about the processing characteristics of the polishing operation, and the data is fit to the appropriate curve to define the model.

Experiments (DOE) are conducted in which layer 230 is polished; however, polishing stops before film layer 220 is reached. Data relating to the control parameters (typically being manipulated by a process recipe) and the measured values for the film characteristic of interest are obtained. By way of example, polishing time, polishing pad down forces and velocity, slurry flow and composition, conditioning time, conditioning disk down forces and velocity, oscillating speeds of both the conditioning disk and the wafer carrier are variables that may be used as control parameters in developing a process model. Next, the lower layer 220 is polished and similar data for control parameters and the measured values for the film characteristic of interest are obtained.

In developing a model, each layer is treated as an independent film and a separate model is developed to describe the CMP process for each layer based on data obtained from the DOE data for that layer. Regression methods (or any other suitable method) may be used to determine a model that describes the behavior of the process within the range of inputs that were used in the experiments. The model can be represented as raw data that reflects the system, or it can be represented by equations, for example multiple input-multiple output linear, quadratic and nonlinear equations, which describe the relationship among the variables of the system.

In one or more embodiments of the present invention, a model for CMP processing of a multi-layer film having a layer A and layer B is defined as shown in eq. (1),

Yₜ=Y_{A}+Y_{B}, (1)

where

Yₜ is the model for a CMP process for a multi-layer wafer;

Y_{A} is the model for a CMP process for the first layer A of the wafer; and

Y_{B} is the model for a CMP process for the second layer B of the wafer.

In one or more embodiments of the present invention a linear equation is used to define the polishing of the first and second layers of the wafer. The relationships are given by eq. (2) and eq. (3), respectively.

Y_{A}=C₁X_{A}+B₁ (2)

Y_{B}=C₂X_{B}+B₂ (3)

In eqs. (2) and (3), Y is the target or observed film property, X is a control parameter, C is a factor such as material removal rate associated with the control parameter, and B is the intercept of the curve. B may play a role in defining the initial conditioning; however, it is the difference between predicted and actual values that is relevant in updating the model.

By way of example, the target property “Y” is film thickness or film uniformity. The control parameter(s) “X” is one or more polishing parameters that can be varied to obtain the desired target film property. Exemplary polishing parameters include polishing time, polishing pad down forces and velocity, slurry flow and composition, conditioning time, conditioning disk down forces and velocity, oscillating speeds of both the conditioning disk and the wafer carrier. When several polishing parameters (e.g., X₁, X₂, X₃. . . ) are used to define the polishing model for a layer of the wafer, each of the parameters contributing to target property “Y” may be combined in a single equation, which defines the weighted contribution of each parameter to the target property.

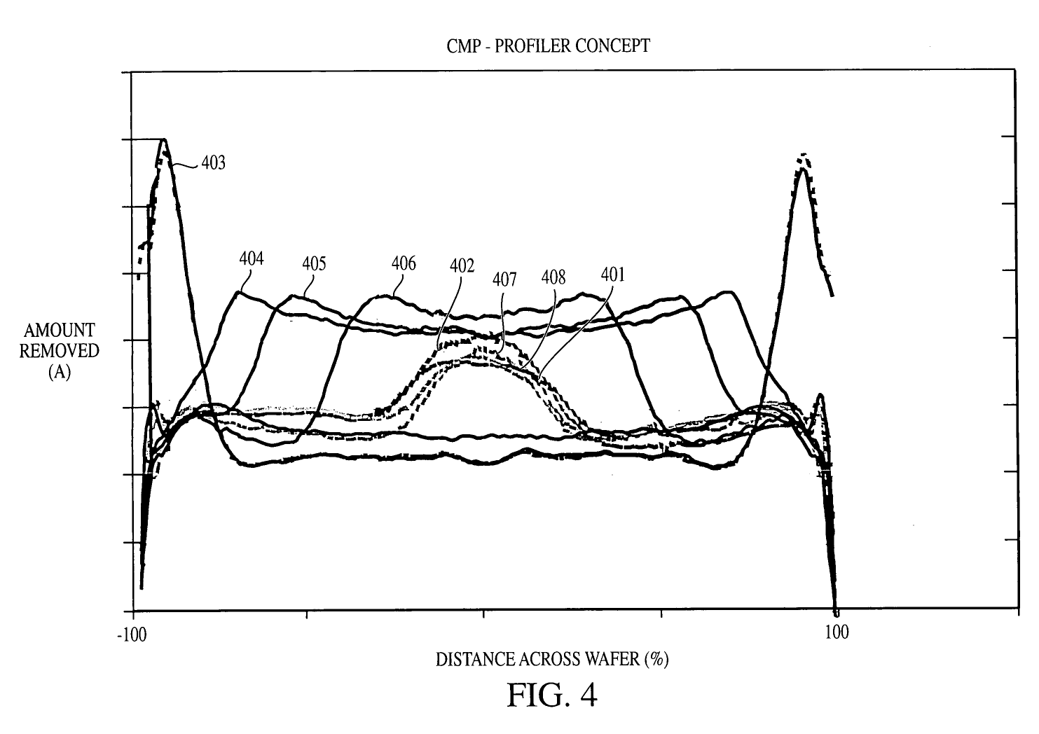

Any model that relates the processing variables to the output characteristic of the wafer may be used in development of the model according to one or more embodiments of the present invention. The model may vary in complexity and may be defined by a plurality of processing parameters and/or processing steps. By way of example, FIG. 4 shows a CMP profile for eight successive polishing steps 401 through 408 for a single wafer. Each polishing step removes a subset of the total material to be polished from the substrate surface. Moreover, the material removal profile generated by each polishing step may be different, as is seen by comparison of profiles, e.g., curves 401 and 403. The final thin film thickness is a function of the sum of the individual polishing step material removal profiles, which desirably produces a uniform wafer thickness across the surface. According to one or more embodiments of the present invention, a subset of the polishing steps are used to remove the top layer, e.g., layer 230, without engaging the second layer, e.g., layer 220.

A model having multiple, e.g., five, polishing steps such as is illustrated in FIG. 4 may be defined as shown in eq. (4):

Y_{A}=c₁ⱼ·t₁+c₂ⱼ·t₂+c₃ⱼ·t₃+c₄ⱼ·t₄+c₅ⱼ·t₅+B, (4)

Where Y_{A} is the amount of material removed for layer A of the wafer; t₁, t₂, t₃, t₄, and t₅ are the polishing times for polishing steps 1, 2, 3, 4, and 5, respectively; and c₁ⱼ, c₂ⱼ, c₃ⱼ, c₄ⱼ; and c₅ⱼ are removal rates for region j in polishing steps 1, 2, 3, 4, and 5, respectively. Additional parameters may be included in the model.

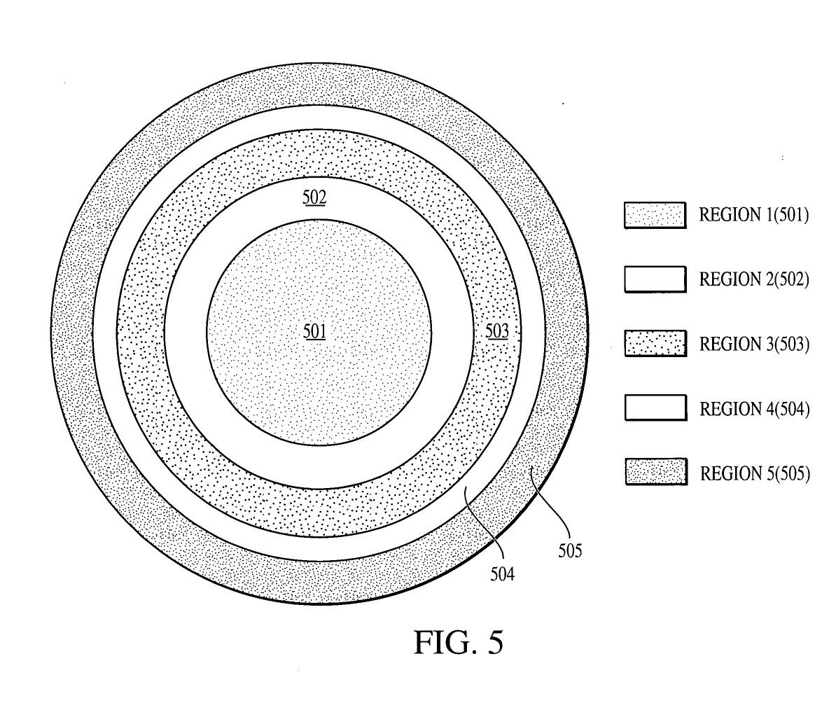

Another exemplary model relies on removal rate profiles based on regions of the wafer. As is shown in FIG. 5, a wafer may be divided into radial regions, e.g., regions 501 through 505, of varying width and area. The size and location of the regions also may vary and may be selected based upon the effect of certain polishing parameters on the wafer in that region. The number, size and location of regions may be selected based upon the complexity of the wafer material removal rate profile. In at least some embodiments of the present invention, it is desirable that the profile in any given region be substantially uniform, particularly in those cases where a number of wafer thickness measurement within a region are averaged to define the region-averaged thickness profile. Thus, at the edges where edge effects can be dramatic, narrow regions encompassing only the outer regions may be selected. Near the center of the wafer where polishing effects may be subtler, a larger region may be defined. The regions are defined such that all azimuthal variation is averaged out since the CMP tool cannot correct for such variation. Film thickness measurements taken within a region of the wafer are averaged to give the average thickness for that region. According to one or more embodiments of the present invention, this model is developed separately for each layer of the multi-layer film.

Exemplary polishing variables (control parameters), which may be included in this model include, but are not limited to, polishing time, polishing pad down forces and velocity, slurry flow and composition, conditioning time, conditioning disk down forces and velocity, and sweep speeds of both the conditioning disk and the wafer carrier. The processing variable for a basic model is typically polishing time; however, additional parameters can be included in the model, as needed or desired.

In at least some embodiments of the present invention, the model may be further augmented to include the effect of the tool state. The tool state represents the effect of wear, use and aging on the tool, and includes the condition of the conditioning disk and polishing pad, represented by disk life and pad life, and also includes idle time. This functionality may be expressed as a scaling factor.

CMP systems have evolved from single-stage units that can only perform one type of polish step at a time, to versatile systems that have up to three independent polishing stations (platens) that can perform a multi-platen, multi-step process. A CMP process may include the transport of a sample from polishing station (platen) to polishing station (platen). One type of CMP process distributes wafer removal among the various platens, and each platen will have a full set of polishing steps to achieve the desired material removal for that platen. Any combination of removal is possible. Thus, by way of example, where it is desired to remove 6000 Å of material in total, 1000 Å may removed from the polishing station at platen 1, 3000 Å may be removed at platen 2, and 2000 Å may be removed at platen 3. In the implementation of the model, for example, platen 1 may be used to polish the top thin layer 230 of the multi-layer film, and platens 2 and 3 may be used to polish the second thicker layer 220 of the multi-layer film. The polishing recipe for each platen may be the same or different.

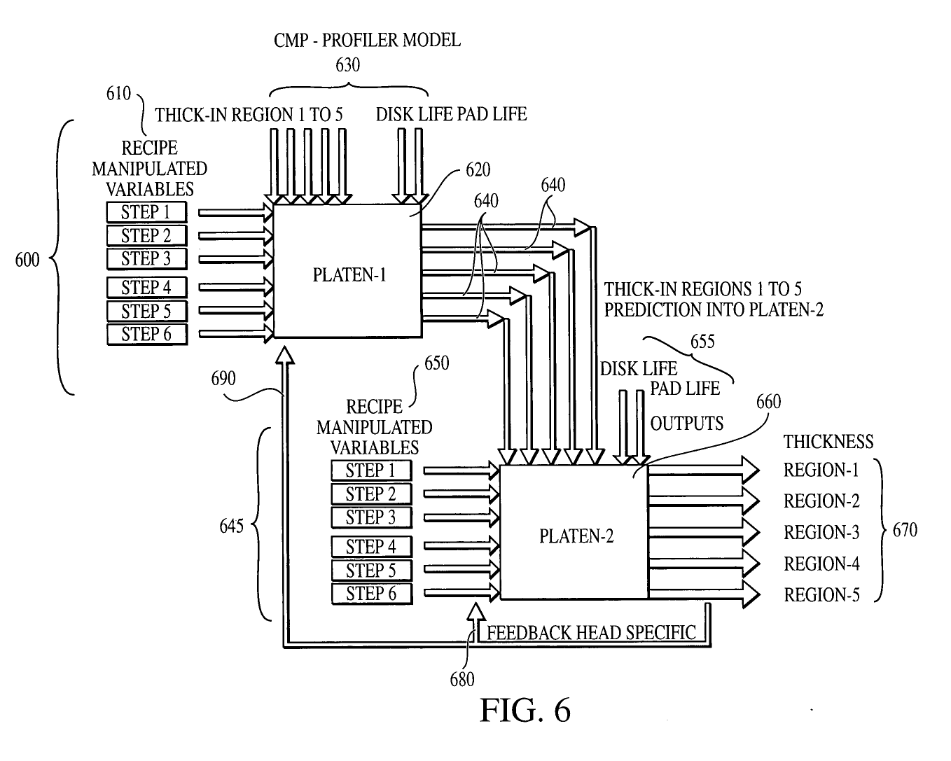

A process model that accounts for the effects of multiple platens that perform similar or different polishing steps is illustrated in FIG. 6. In a first phase 600 of the model, the polishing recipe 610 (here, 6 steps) for platen 1 620 is determined (the “first polishing process”). Process input data 630, such as incoming wafer thickness for the defined regions of the pre-polished wafer (wafer state), disk life and pad life (tool state), are input into the model. The wafer is polished and final wafer thicknesses 640 for each of the wafer regions is measured. Post-polished region thicknesses 640 from the first polishing process are used as input data in a second phase 645 of the model development. A second polishing recipe 650 is carried out on platen 2 660, which can be the same as or different from that carried out on platen 1 620. Tool state 655, such as pad life and disk life relating to the pad and conditioning disk used on platen 2 660, are also included in the model. Final thickness measurements 670 are taken and used in the model development. Thus, one or more embodiments of the present invention can accommodate a model that involves multiple polishing processes on multiple platens having different tool states. The model is extremely versatile and able to accommodate highly complex polishing scenarios.

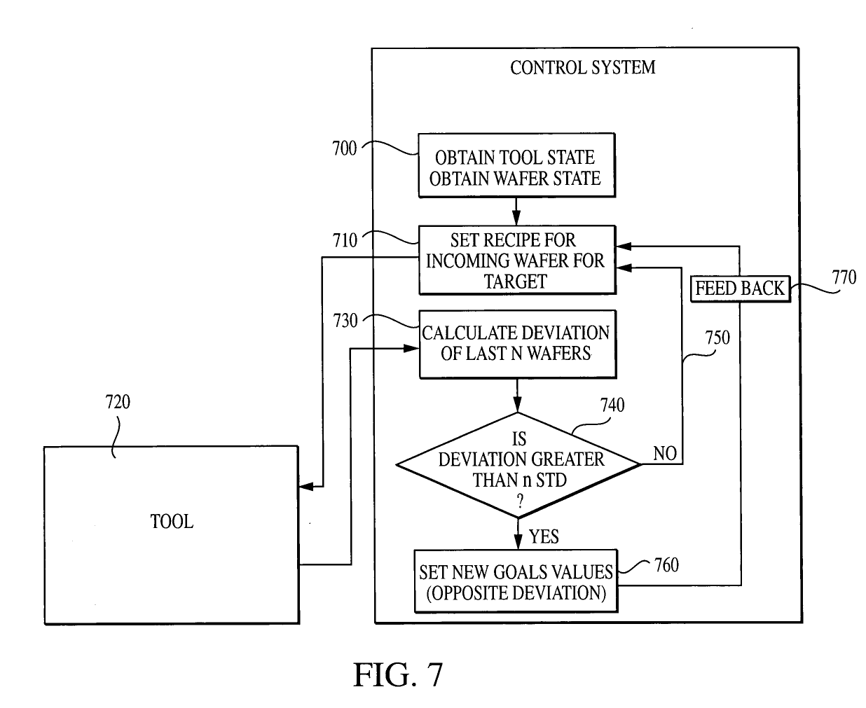

According to at least some embodiments of the present invention, an initial model developed as described herein above is used in at least some embodiments of the present invention to control the run-to-run uniformity of the polishing process and to provide a feedback loop for updating the polishing recipe. For example, in the model described in FIG. 6, platen-specific feedback 680 and 690 are provided to platens 660 and 620, respectively. According to the processing flow diagram in FIG. 7, initial processing conditions, e.g., tool state and wafer state are identified that will provide a desired wafer removal rate profile in step 700 for a multilayer sample. The initial conditions may be determined empirically or by using the processing model of at least one embodiment of the present invention. If a processing model is used, a controller can use this model to calculate step times and processing parameters to polish an incoming profile on a multilayer sample to a target flat profile with a desired thickness as shown in step 710. Wafers are polished according to the initial polishing recipe in the CMP tool at step 720. The thicknesses of the polished wafers are measured and deviation from the predicted thickness is determined in step 730. In step 740, it is determined whether the deviation exceeds an established tolerance. If the deviation is within acceptable ranges, no changes are made to the polishing recipe and the controller instructs the tool to reuse the existing recipe in step 750. If the deviation is outside acceptable limits, new target parameters are set in step 760 and are fedback in step 770 into the controller where the polishing recipe is optimized according to an updated model that takes the deviation from the predicted value into consideration. The polishing step may be repeated and further updates of the polishing recipe are possible.

Additional detail on the development and implementation of CMP polishing feedforward and feed backward process control is found in co-pending application U.S. application Ser. No. 09/943,955, filed Aug. 31, 2002 and entitled “Feedback Control of a Chemical Mechanical Polishing Device Providing Manipulation of Removal Rates Profiles”, which is hereby incorporated in its entirety by reference.

Additional apparatus utilized to implement the feedforward and feedback loop include a film thickness measurement (metrology) tool to provide thickness data needed to calculate wafer material removal rate. The tool may be positioned on the polishing apparatus so as to provide in-line, in situ measurements, or it may be located remote from the polishing apparatus. The tool may use optical, electrical, acoustic or mechanical measurement methods. A suitable thickness measurement device is available from Nanometrics (Milpitas, Calif.) or Nova Measuring Instruments (Phoenix, Ariz.). A computer may be utilized to calculate the optimal pad conditioning recipe based upon the measured film thickness and calculated removal rate, employing the models and algorithm provided according to the present invention. A suitable integrated controller and polishing apparatus (Mirra with iAPC or Mirra Mesa with iAPC) is available from Applied Materials, California.

Exemplary semiconductor wafers that can be polished using the concepts discussed herein including, but are not limited to those made of silicon, tungsten, aluminum, copper, BPSG, USG, thermal oxide, silicon-related films, and low k dielectrics and mixtures thereof. The present invention may be practiced using any number of different types of conventional CMP polishing pads. There are numerous polishing pads in the art that are generally made of urethane or other polymers. Exemplary polishing pads include Epic™ polishing pads (Cabot Microelectronics Corporation, Aurora Ill.) and Rodel® IC1000, IC1010, IC1400 polishing pads (Rodel Corporation, Newark, Del.), OXP series polishing pads (Sycamore Pad), Thomas West Pad 811, 813, 815, 815-Ultra, 817, 826, 828, 828-E1 (Thomas West).

Furthermore, any number of different types of slurry can be used in conjunction with aspects of the present invention. There are numerous CMP polishing slurries in the art, which are generally made to polish specific types of metals in semiconductor wafers. Exemplary slurries include Semi-Sperse® (available as Semi-Sperse® 12, Semi-Sperse® 25, Semi-Sperse® D7000, Semi-Sperse® D7100, Semi-Sperse® D7300, Semi-Sperse® P1000, Semi-Sperse® W2000, and Semi-Sperse® W2585) (Cabot Microelectronics Corporation, Aurora Ill.), Rodel ILD1300, Klebesol series, Elexsol , MSW1500, MSW2000 series, CUS series and PTS (Rodel).

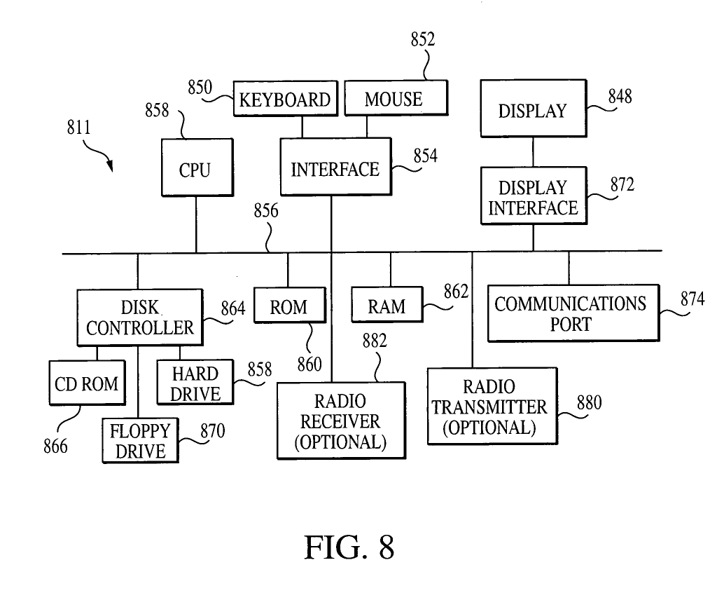

Various aspects of the present invention that can be controlled by a computer can be (and/or be controlled by) any number of control/computer entities, including the one shown in FIG. 8. Referring to FIG. 8 a bus 856 serves as the main information highway interconnecting the other components of system 811. CPU 858 is the central processing unit of the system, performing calculations and logic operations required to execute the processes of embodiments of the present invention as well as other programs. Read only memory (ROM) 860 and random access memory (RAM) 862 constitute the main memory of the system. Disk controller 864 interfaces one or more disk drives to the system bus 856. These disk drives are, for example, floppy disk drives 870, or CD ROM or DVD (digital video disks) drives 866, or internal or external hard drives 868. These various disk drives and disk controllers are optional devices.

A display interface 872 interfaces display 848 and permits information from the bus 856 to be displayed on display 848. Display 848 can be used in displaying a graphical user interface. Communications with external devices such as the other components of the system described above can occur utilizing, for example, communication port 874. Optical fibers and/or electrical cables and/or conductors and/or optical communication (e.g., infrared, and the like) and/or wireless communication (e.g., radio frequency (RF), and the like) can be used as the transport medium between the external devices and communication port 874. Peripheral interface 854 interfaces the keyboard 850 and mouse 852, permitting input data to be transmitted to bus 856. In addition to these components, system 811 also optionally includes an infrared transmitter and/or infrared receiver. Infrared transmitters are optionally utilized when the computer system is used in conjunction with one or more of the processing components/stations that transmits/receives data via infrared signal transmission. Instead of utilizing an infrared transmitter or infrared receiver, the computer system may also optionally use a low power radio transmitter 880 and/or a low power radio receiver 882. The low power radio transmitter transmits the signal for reception by components of the production process, and receives signals from the components via the low power radio receiver. The low power radio transmitter and/or receiver are standard devices in industry.

Although system 811 in FIG. 8 is illustrated having a single processor, a single hard disk drive and a single local memory, system 811 is optionally suitably equipped with any multitude or combination of processors or storage devices. For example, system 811 may be replaced by, or combined with, any suitable processing system operative in accordance with the principles of embodiments of the present invention, including sophisticated calculators, and hand-held, laptop/notebook, mini, mainframe and super computers, as well as processing system network combinations of the same.

Exemplary computer readable memory medium may be used for storing computer readable code or instructions, and, for example, may be used with disk drives illustrated in FIG. 8. Typically, memory media such as floppy disks, or a CD ROM, or a digital video disk will contain, for example, a multi-byte locale for a single byte language and the program information for controlling the above system to enable the computer to perform the functions described herein. Alternatively, ROM 860 and/or RAM 862 illustrated in FIG. 8 can also be used to store the program information that is used to instruct the central processing unit 858 to perform the operations associated with the instant processes. Other examples of suitable computer readable media for storing information include magnetic, electronic, or optical (including holographic) storage, some combination thereof, etc. In addition, at least some embodiments of the present invention contemplate that the medium can be in the form of a transmission (e.g., digital or propagated signals).

In general, it should be emphasized that various components of embodiments of the present invention can be implemented in hardware, software or a combination thereof. In such embodiments of the present invention, the various components and steps would be implemented in hardware and/or software to perform the functions of the present invention. Any presently available or future developed computer software language and/or hardware components can be employed in such embodiments of the present invention. For example, at least some of the functionality mentioned above could be implemented using the C, C++, or any assembly language appropriate in view of the processor(s) being used. It could also be written in an interpretive environment such as Java and transported to multiple destinations to various users.

Although various embodiments of the present invention that incorporate the teachings of the present invention have been shown and described in detail herein, those skilled in the art can readily devise many other varied embodiments of the present invention that incorporate these teachings.

What is claimed is:

1. A computer-implemented method for updating a process recipe in a CMP process for a multilayer wafer, comprising the steps of:
(a) inputting a model for CMP processing of a wafer having at least first and second layers comprising at least one control parameter, said model comprising a first component that predicts a value for a characteristic of the first layer and a second component that predicts a value for a characteristic of the second layer;
(b) determining a process recipe based upon the model of step (a);
(c) receiving a measured value of the characteristic of the first layer and/or the characteristic of the second layer for a wafer processed according to the process recipe of step (b); and
(d) determining an updated model based upon the difference between the measured value and the predicted value of the characteristic.

2. The method of claim 1, wherein the model determines a first process recipe for the first layer of the wafer and a second process recipe for the second layer of the wafer.

3. The method of claim 1, wherein the model is defined as:
Yₜ=Y_{A}+Y_{B},
where
Yₜ is the model for a CMP process for a multi-layer wafer;
Y_{A} is the model for a CMP process for the first layer of the wafer; and
Y_{B} is the model for a CMP process for the second layer of the wafer.

4. The method of claim 1, wherein the characteristic of the first and second layers of the wafer comprises film thickness, and/or the control parameter comprises polishing time.

5. The method of claim 1, wherein the model of step (a) defines a plurality of regions on a wafer and a measured value for the wafer characteristic for each of the plurality of regions is received in step (c).

6. The method of claim 1, wherein the processing recipe comprises a plurality of polishing steps.

7. The method of claim 1, wherein the model accounts for a tool state of a tool used in the CMP processing of a wafer.

8. The method of claim 1, further comprising developing a model, said model development comprising the steps of
(e) inputting pre-polished wafer characteristics for one or more wafers;
(f) receiving measured values of the wafer characteristics for the one or more wafers processed according to a processing recipe;
(g) providing a model defining the effect of tool state on polishing effectiveness; and
(h) recording the pre-polished and post-polished wafer characteristic on a recordable medium.

9. The method of claim 8, wherein model development further comprises fitting the data to a curve that establishes a relationship between the wafer characteristic and the control parameter.

10. A method of controlling a characteristic of a wafer in a CMP operation, comprising the steps of:
(a) providing a model for CMP processing of a wafer having at least first and second layers comprising at least one control parameter capable of being controlled, comprising a first component that predicts a value for a characteristic of the first layer and a second component that predicts a value for a characteristic of the second layer;
(b) polishing a wafer using a first polishing recipe based upon the model of step (a);
(c) measuring the wafer characteristic for a wafer processed according to the process recipe of step (b); and
(d) determining an updated model based upon the difference between the measured value and the predicted value of the wafer characteristic.

11. The method of claim 10, further comprising:
determining an updated process recipe based upon the updated model of step (d).

12. The method of claim 10, wherein the model determines a first process recipe for the first layer of the wafer and a second process recipe for the second layer of the wafer.

13. The method of claim 10, wherein the model accounts for the tool state of a tool used in the CMP processing of a wafer.

14. The method of claim 10, wherein the model is defined as:
Yₜ=Y_{A}+Y_{B},
where
Yₜ is the model for a CMP process for a multi-layer wafer;
Y_{A} is the model for a CMP process for the first layer of the wafer; and
Y_{B} is the model for a CMP process for the second layer of the wafer.

15. The method of claim 10, wherein the characteristic of the first and second layers of the wafer comprises film thickness, and/or the control parameter comprises polishing time.

16. The method of claim 10, wherein the model defines a plurality of regions on a wafer and identifies a wafer material removal rate in a polishing step of a polishing process for each of the regions.

17. The method of claim 10, wherein the polishing process comprises a plurality of polishing steps.

18. The method of claim 16, wherein the plurality of regions in the model of step (a) comprises regions extending radially outward from a center point on the wafer.

19. The method of claim 10, wherein the polishing of step (b) comprises polishing the wafer at a plurality of polishing stations.

20. The method of claim 19, wherein determining the updated polishing model of step (d) comprises calculating updated models for each of the plurality of polishing stations.

21. The method of claim 20, wherein the updated polishing model for each of the plurality of polishing stations accounts for the tool state of the individual polishing stations.

22. The method of claim 19, wherein, the initial wafer thickness for each of the polishing stations is provided by the prediction from previous polishing stations.

23. An apparatus for polishing a wafer in a CMP operation having controlled characteristics, comprising:
(a) a model for comprising at least one control parameter capable of being controlled for CMP processing of a wafer having at least first and second layers, comprising a first component that predicts a value for a characteristic of the first layer and a second component that predicts a value for a characteristic of the second layer;
(b) polishing means for polishing a wafer using a first polishing recipe based upon the model of step (a);
(c) measuring means for measuring the wafer characteristic for a wafer processed according to the process recipe of step (b); and
(d) calculating means for determining an updated model based upon the difference between the measured value and the predicted value of the wafer characteristic.

24. The apparatus of claim 23, wherein the model defines a first process recipe for the first layer of the wafer and a second process recipe for the second layer of the wafer.

25. The apparatus of claim 23, wherein the model accounts for the tool state of a tool used in the CMP processing of a wafer.

26. The apparatus of claim 23, wherein the characteristic of the first and second layers of the wafer comprises film thickness, and/or the control parameter comprises polishing time.

27. The apparatus of claim 23, wherein the model defines a plurality of regions on a wafer and identifies a wafer material removal rate in a polishing step of a polishing process for each of the regions.

28. The apparatus of claim 27, wherein the polishing process comprises a plurality of polishing steps.

29. The apparatus of claim 23, wherein the polishing of step (b) comprises polishing the wafer at a plurality of polishing stations.

30. An system for polishing a wafer in a CMP operation having controlled characteristics, comprising:
(a) a model for comprising at least one control parameter capable of being controlled for CMP processing of a wafer having at least first and second layers, comprising a first component that predicts a value for a characteristic of the first layer and a second component that predicts a value for a characteristic of the second layer;
(b) CMP polishing station for polishing a wafer using a first polishing recipe based upon the model of step (a);
(c) a metrology tool for measuring the wafer characteristic for a wafer processed according to the process recipe of step (b); and
(d) a computer for calculating an updated model based upon the difference between the measured value and the predicted value of the wafer characteristic.
